(19) United States
(12) Patent Application Publication
(10) Pub. No.: US 2022/0100296 A1
(43) Pub. Date: Mar. 31, 2022

(54) FLEXIBLE TOUCH SENSOR ELECTRODE AND MANUFACTURING METHOD THEREFOR

(71) Applicant: SHENZHEN ROYOLE TECHNOLOGIES CO., LTD., Shenzhen, Guangdong (CN)

(72) Inventor: Xiaohua Lei, Shenzhen (CN)

(21) Appl. No.: 17/425,312

(22) PCT Filed: Jan. 25, 2019
(86) PCT No.: PCT/CN2019/073247

§ 371 Date: Jul. 22, 2021

(51) Int. Cl. G06F 3/041

(52) U.S. Cl. CPC G06F 3/041; G06F 2203/04103; G06F 2203/04102

(57) ABSTRACT

Flexible touch sensor electrode includes substrate layer metal wire layer, protective layer and lead structure. Substrate layer is made of flexible insulating material; metal wire layer is flexible film layer made of nano-metal wire, covers at least part of surface of substrate layer and is used for sensing external touch operation and generating a corresponding electrical signal; protective layer is made of flexible insulating material and covers at least part of surface of metal wire layer away from substrate layer; metal wire layer is provided with contact area for establishing electrical connection to outside; within range of contact area protective layer is all or partially removed; lead structure includes covering portion and leading-out portion, covering portion covers and directly contacts contact area to establish electrical connection and leading-out portion extends from covering portion and is used to electrically connect metal wire layer to outside. Further provided is manufacturing method for electrode.

### TECHNICAL FIELD

The present disclosure relates to the technical field of flexible display screens, in particular to a flexible touch sensor electrode and a manufacturing method therefor.

### BACKGROUND ART

As a new class of high-tech electronic products, flexible display screens have been increasingly widely used in many fields. In order to make the flexible display screen have the touch control function, the flexible touch sensor electrodes must be arranged in the flexible display screen. At present, in the field of flexible display screens, transparent conductive films (such as transparent conductive films based on nano metal wires) are often used to manufacture flexible touch sensor electrodes, and conductive ink is printed on the transparent conductive film, and the conductive ink is used to form the outgoing line of flexible touch sensor electrodes.

In practical applications, in order to provide protection for the transparent conductive film layer, it is usually necessary to coat a protective layer on the transparent conductive film. However, because the conductive ink needs to be printed on the transparent conductive film as the outgoing line of the flexible film sensor electrode, in order to ensure that the conductive ink is in good contact with the transparent conductive film, the protective layer usually has to be designed to be very thin, so as to avoid forming unnecessary shielding between the conductive ink and the transparent conductive film; in addition, it is necessary to partially expose many nano metal wires on the transparent conductive film in order to form sufficient contact with the conductive ink. Obviously, in the above structure, because the thickness of the protective layer is very thin and many nano metal wires are partially exposed outside, the protective effect of the protective layer is inevitably poor, and it is difficult to effectively prevent damage to the transparent conductive film, especially the exposed nano metal wires are prone to undergo chemical reactions with external pollutants such as oxygen, moisture, sulfides, halides, organic acids, etc., resulting in the failure of nano metal wires. If the thickness of the protective layer is increased in order to improve the protective performance, the thicker protective layer may hinder the full contact between the conductive ink and the transparent conductive film and then affect the electrical performance.

### SUMMARY

The present disclosure provides a flexible touch sensor electrode, which is used to solve the problems in the prior art that the protective effect of the protective layer of the flexible touch sensor electrode is not good, and the electrical performance may also be affected.

The present disclosure also correspondingly provides a method for manufacturing flexible touch sensor electrode.

According to the embodiments of the present disclosure, a flexible touch sensor electrode is provided, including a substrate layer, a metal wire layer, a protective layer and a lead structure. The substrate layer is made of a flexible insulating material; the metal wire layer is a flexible film layer made on the basis of a nano metal wire, covers at least a part of the surface of the substrate layer and is used for sensing an external touch operation and generating a corresponding electrical signal according to the touch operation; the protective layer is made of a flexible insulating material and covers at least the part of the surface of the metal wire layer facing away from the substrate layer; and the metal wire layer is provided with a contact area for establishing an electrical connection to the outside, and within the range of the contact area, the protective layer is in whole or in part removed; the lead structure comprises a covering portion and a leading-out portion, wherein the covering portion covers the contact area and directly contacts the contact area so as to establish the electrical connection, and wherein the leading-out portion extends from the covering portion and is used to electrically connect the metal wire layer to the outside.

Preferably, a connecting hole extending to the inside of the metal wire layer is provided in the range of the contact area, a conductive pillar corresponding to the connecting hole is extendedly formed at the bottom of the covering portion, and the conductive pillar extends into the connecting hole and contacts the metal wire layer at the inner wall of the connecting hole, thereby establishing an electrical connection between the metal wire layer and the lead structure.

Preferably, the connecting hole completely penetrates the metal wire layer and extends to the surface of the substrate layer, and the end of the conductive pillar is directly connected to the substrate layer.

Preferably, within the range of the contact area, a portion of the protective layer corresponding to the connecting hole is removed.

Preferably, all parts of the contact area not covered by the protective layer are directly covered and contacted by the covering portion.

Preferably, the covering portion also covers a part of the protective layer outside the range of the contact area.

Preferably, the substrate layer, the metal wire layer, and the protective layer are all transparent flexible films.

Preferably, the substrate layer is made of an amorphous polymer material.

Preferably, the protective layer is made of an etchable polymer resin material or an inorganic oxide material.

Preferably, the lead structure is made of conductive ink by printing means.

The present disclosure also provides a method for manufacturing flexible touch sensor electrode, including:

forming a substrate layer;

forming a metal wire layer on the substrate layer;

forming a protective layer on the metal wire layer;

determining a contact area on the metal wire layer, and removing all or part of the protective layer on the contact area; and

forming a lead structure including a covering portion and a leading-out portion, so that the covering portion covers the contact area and directly contacts the contact area to establish an electrical connection, wherein the leading-out portion extends from the covering portion to electrically connect the metal wire layer with the outside.

Preferably, the forming a metal wire layer on the substrate layer includes:

mixing the nano metal wires in a solvent to form a nano metal wire dispersion;

coating the nano metal wire dispersion on the substrate layer;

volatilizing the solvent in the nano metal wire dispersion through drying treatment measures; and

fixing the nano metal wire on the substrate layer by fixing treatment measures.

Preferably, the forming a protective layer on the metal wire layer includes:

selecting an etchable polymer resin material or an inorganic oxide material as the material of the protective layer; and

coating the material of the protective layer on the metal wire layer by at least one of printing, spraying, physical deposition, chemical deposition, and electroplating.

Preferably, the removing all or part of the protective layer on the contact area includes:

performing a perforation (trepanning) treatment in the range of the contact area by at least one of laser etching, chemical wet etching, and physical cutting die imprinting, so as to form a connecting hole that completely penetrates the protective layer and extends into the metal wire layer, so that the part of the protective layer corresponding to the connecting hole is removed.

Preferably, the removing all or part of the protective layer on the contact area includes:

removing all or part of the protective layer on the contact area by at least one of laser etching, chemical wet etching, and physical cutting die imprinting.

Preferably, the forming a lead structure including a covering portion and a leading-out portion includes:

printing conductive ink on the surface of the contact area to form the covering portion; and

printing the leading-out portion extending from the covering portion with conductive ink on the protective layer outside the contact area.

Preferably, the method further includes:

performing a perforation treatment in the area of the contact area where the protective layer is removed by at least one of laser etching, chemical wet etching, and physical cutting die imprinting, so as to form a connecting hole extending into the metal wire layer in the area.

Preferably, the forming a lead structure including a covering portion and a leading-out portion includes:

printing conductive ink on the surface of the contact area to form the covering portion; at the same time, allowing the conductive ink to enter the connecting hole to fill the connecting hole, so as to form, after curing, a conductive pillar for establishing electrical connection with the metal wire layer through contact; and

printing the leading-out portion extending from the covering portion with conductive ink on the protective layer outside the contact area.

According to the above-mentioned embodiments, in the flexible touch sensor electrode provided in the present disclosure, the surfaces of both sides of the metal wire layer are respectively protected by the substrate layer and the protective layer, which can effectively prevent the metal wire layer from being damaged by external contaminants; within the range of the contact area, the protective layer is completely or partly removed, and further connecting holes for allowing the lead structure to extend to the inside of the metal wire layer can be provided to ensure that the contact between the metal wire layer and the lead structure is not hindered by the protective layer, so as to establish a good electrical connection between the metal wire layer and the lead structure, and thus improve the electrical performance of the flexible touch sensor electrode; and since the protective layer does not hinder the electrical connection between the metal wire layer and the lead structure in the contact area, the protective layer can be manufactured to have a sufficient thickness to provide sufficient protection for the metal wire layer, so as to significantly improve the reliability of the flexible touch sensor electrode and prolong the service life, thereby effectively solving the problem in the prior art that the protective layer of the flexible touch sensor electrode has poor protection effect and may also affect the electrical performance.

### BRIEF DESCRIPTION OF DRAWINGS

FIG. 1 shows a schematic diagram of the structure of a flexible touch sensor electrode provided by a preferred embodiment of the present disclosure.

FIG. 2 shows a schematic sectional diagram of a partial structure of the flexible touch sensor electrode shown in FIG. 1.

FIG. 3 shows a schematic sectional diagram of a substrate layer and a metal wire layer used to manufacture the flexible touch sensor electrode shown in FIG. 1.

FIG. 4 shows a schematic sectional diagram of a protective layer formed on the metal wire layer shown in FIG. 3.

FIG. 5 shows a schematic sectional diagram of performing perforation on the metal wire layer and the protective layer shown in FIG. 4.

FIG. 6 shows a schematic sectional diagram of a partial structure of a flexible touch sensor electrode provided by another preferred embodiment of the present disclosure.

FIG. 7 shows a schematic sectional diagram of a substrate layer, a metal wire layer, and a protective layer that has undergone a partial removal process for manufacturing the flexible touch sensor electrode shown in FIG. 6.

FIG. 8 shows a schematic sectional diagram of a partial structure of a flexible touch sensor electrode provided by yet another preferred embodiment of the present disclosure.

FIG. 9 shows a schematic sectional diagram of a substrate layer, a metal wire layer that has undergone perforation treatment, and a protective layer that has undergone a partial removal process for manufacturing the flexible touch sensor electrode shown in FIG. 8.

### DETAILED DESCRIPTION OF EMBODIMENTS

In order to make the purposes, technical solutions, and advantages of the present disclosure clearer, the following further describes the present disclosure in detail with reference to the accompanying drawings in combination with embodiments.

Please refer to FIG. 1, the first preferred embodiment of the present disclosure provides a flexible touch sensor electrode 100, wherein the flexible touch sensor electrode 100 has a flexible transparent conductive film based on nano metal wires, on the one hand, it has sufficient flexibility to meet the needs of a flexible display screen, on the other hand, it can also sense the user's touch and convert the pressure of the touch into an electrical signal.

The transparent conductive film includes a substrate layer 110 and a metal wire layer 120. The substrate layer 110 may be a film made of a flexible insulator material, preferably a transparent flexible film made of, for example, an amorphous polymer material, such as PET (polyethylene terephthalate) and other plastic material. The metal wire layer 120 is preferably a transparent flexible film layer made based on nano metal wires (such as copper nanowires or silver nanowires), which has both good conductivity and light transmittance, and covers at least part of the surface of the substrate layer 110, so as to sense external touch operations, and generate corresponding electrical signals according to the touch operations. The number of metal wire layers 120 may be multiple (for example, three metal wire layers 120 are shown in FIG. 1, in other embodiments, the number of metal wire layers 120 may also be other numbers), which respectively cover the surfaces of a plurality of predetermined areas of the substrate layer 110. A contact area 130 for establishing an electrical connection for the metal wire layer 120 may be formed at a certain position of each metal wire layer 120. The specific shape and position of the contact area 130 may be determined according to the specific conditions of the metal wire layer 120, for example, in the embodiment shown in FIG. 1, the metal wire layer 120 is a strip-type coating area, and the contact area 130 is an electrical connection portion formed at one end of the metal wire layer 120; obviously, in other embodiments, the shape and arrangement form of the metal wire layer 120 and its contact area 130 can also be adjusted accordingly.

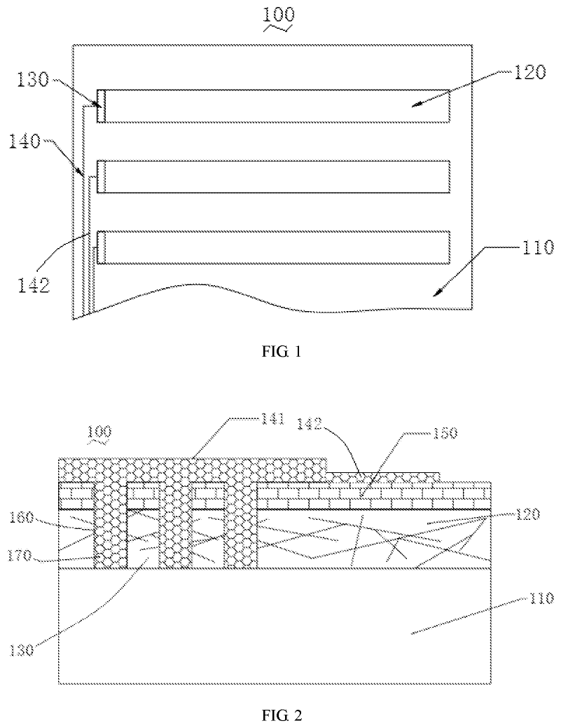

Please refer to FIG. 2 together, the flexible touch sensor electrode 100 further includes a lead structure 140, wherein the lead structure 140 is formed by a conductive ink layer printed on the transparent conductive film, preferably formed on the surface of the metal wire layer 120 facing away from the substrate layer 110, particularly preferably formed on the surface of the contact area 130 facing away from the substrate layer 110. In this embodiment, the lead structure 140 includes a covering portion 141 and a leading-out portion 142. The covering portion 141 is a conductive ink layer covering a certain area of the surface of the transparent conductive film (preferably on the entire surface of the contact area 130), and the leading-out portion 142 is an elongated lead made of conductive ink, which is leaded out from the covering portion 141 and extends along the surface of the transparent conductive film, and its end is connected to other external electronic devices that need to be electrically connected to the metal wire layer 120 (not shown in the figure), so as to provide the required electrical connection to the metal wire layer 120. Obviously, the number, shape and position distribution of the lead structure 140 can correspond to the metal wire layer 120.

In order to provide complete protection for the flexible touch sensor electrode 100, the flexible touch sensor electrode 100 further includes a protective layer 150. The protective layer 150 is made of a transparent insulating material, for example, a polymer resin material such as epoxy resin, polyurethane resin, acrylate resin and the like can be used, or an inorganic oxide material such as silicon dioxide, silicon nitride and the like may also be used. The protective layer 150 covers at least a part of the surface of the metal wire layer 120 facing away from the substrate layer 110. It can be understood that the covering portion 141 of the lead structure 140 may also extend beyond the contact area 130 to cover a part of the protective layer 150 outside the contact area 130, so that the lead structure 140 is simultaneously bonded to the metal wire layer 120 and the protective layer 150, which is beneficial to improve the firmness of the overall structure.

In particular, in order to enable the metal wire layer 120 to use its contact area 130 to establish a good electrical connection, in this embodiment, the contact area 130 is provided with a plurality of connecting holes 160 extending into the metal wire layer 120. The connecting hole 160 partially penetrates the metal wire layer 120 (that is, the bottom of the connecting hole 160 does not reach the surface of the substrate layer 110) or completely penetrates the metal wire layer 120 (that is, the bottom of the connecting hole 160 reaches the surface of the substrate layer 110), and meanwhile, the part of the protective layer 150 corresponding to the connecting hole 160 is also removed, so that at least part of the area of the metal wire layer 120 located on the inner wall of the connecting hole 160 will not be covered by the protective layer 150, that is, is exposed from the inner wall of the connecting hole 160. The lead structure 140 is provided with conductive pillars 170 corresponding to the connecting holes 160 in number, shape and size, and the conductive pillars 170 are columnar portions extending from the bottom of the covering portion 141 of the lead structure 140, which are inserted into the connecting holes 160 as a physical conductive channel; and the surface of the conductive pillar 170 is in full contact with the inner wall of the corresponding connecting hole 160, that is, in contact with the metal wire layer 120 at the inner wall of the connecting hole 160. In this way, the nano metal wires in the metal wire layer 120 form sufficient contact with the conductive ink in the conductive pillar 170 at the inner wall of the connecting hole 160, thereby establishing a good electrical connection between the metal wire layer 120 and the lead structure 140, so that the electrical signal generated by the metal wire layer 120 can be transmitted to other electronic devices through the lead structure 140.

In the above-mentioned flexible touch sensor electrode 100, both sides of the metal wire layer 120 are respectively protected by the substrate layer 110 and the protective layer 150, which can effectively prevent the metal wire layer 120 from being damaged by external contaminants. In the contact area 130, the metal wire layer 120 is connected to the conductive pillar 170 extending from the lead structure 140 into the connecting hole 160 through the above connecting hole 160, so as to ensure that a good electrical connection is established between the metal wire layer 120 and the lead structure 140, which will not be hindered by the protective layer 150. On the other hand, since the protective layer 150 does not hinder the electrical connection between the metal wire layer 120 and the lead structure 140, the protective layer 150 can be manufactured to have a sufficient thickness, to provide sufficient protection for the metal wire layer 120, so as to effectively improve the reliability of the flexible touch sensor electrode 100 and prolong the service life.

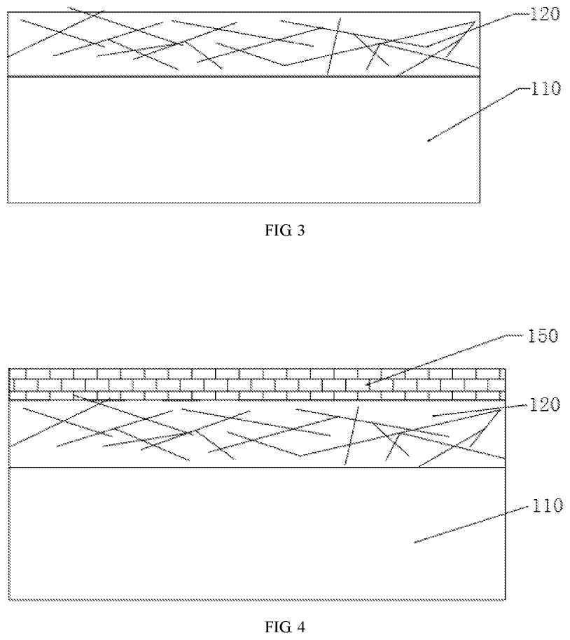

A preferred embodiment of the present disclosure also provides a method for manufacturing a flexible touch sensor electrode, and the method can be used to manufacture the flexible touch sensor electrode 100 as described above. Please refer to FIGS. 3 to 5 together, the method may include the following steps:

S11, forming the substrate layer 110 of the above-mentioned transparent conductive film. As mentioned above, the substrate layer 110 may be a transparent flexible insulator film made of an amorphous polymer material such as PET material.

S12, forming the above-mentioned metal wire layer 120 on the substrate layer 110, as shown in FIG. 3. The method of forming the metal wire layer 120 may be, for example, uniformly mixing nano metal wires in a solvent (such as ethanol, deionized water and isopropanol) to form a nano metal wire dispersion, uniformly coating the nano metal wire dispersion on one surface of the substrate layer 110, and then volatilizing the solvent in the nano metal wire dispersion by drying treatment measures, and then fixing the nano metal wires on the substrate layer 110 by fixing treatment measures, such as pressing (pressurization) and annealing, so as to form a uniform and stable metal wire layer 120 on the substrate layer 110.

S13, forming the above-mentioned protective layer 150 on the metal wire layer 120, as shown in FIG. 4. In this step S13, a protective layer 150 is formed on the surface of the metal wire layer 120 facing away from the substrate layer 110, and the protective layer 150 is used to completely cover the metal wire layer 120. As mentioned above, the material of the protective layer 150 adopts a transparent insulating material, for example, a polymer resin material such as epoxy resin, polyurethane resin, acrylate resin and the like can be used, or an inorganic oxide material such as silicon dioxide, silicon nitride and the like may also be used; particularly preferably, the material of the protective layer 150 is an etchable material, such as a photoresist material that can be removed by UV (ultraviolet) exposure, a resin material that can be removed by a weak base, and the like. The protective layer 150 is formed by uniformly coating the selected transparent insulating material on the metal wire layer 120 by at least one method of printing, spraying, physical deposition, chemical deposition, electroplating and the like.

S14, determining the above-mentioned contact area 130 on the metal wire layer 120, and performing a perforation treatment in the range of the contact area 130, so as to form the above-mentioned connecting hole 160 in the range of the contact area 130 that completely penetrates the protective layer 150 and extends into (preferably penetrates) the metal wire layer 120, as shown in FIG. 5. The specific operation means of the perforation treatment can be selected such as laser etching, chemical wet etching, and physical cutting die imprinting. In this step S14, it is obvious that the part of the protective layer 150 where the connecting hole 160 is provided will be removed, so that at least a part of the area of the metal wire layer 120 located on the inner wall of the connecting hole 160 will not be covered by the protective layer 150.

S15, forming the above-mentioned lead structure 140 including a covering portion 141 and a leading-out portion 142, as shown in FIG. 2, so that the covering portion 141 covers the contact area 130 and directly contacts the contact area 130 to establish an electrical connection, wherein the leading-out portion 142 extends from the covering portion 141 to electrically connect the metal wire layer 120 with the outside. In this step S15, the conductive ink may be printed on the transparent conductive film, for example, the conductive ink may be printed on the surface of the contact area 130 to form the covering portion 141 of the lead structure 140, and further a leading-out portion 142 extending from the covering portion 141 is printed on the protective layer 150 outside the contact area 130, for electrical connection with other electronic devices. Meanwhile, since the above-mentioned connecting hole 160 is formed in the contact area 130, the conductive ink will enter the connecting hole 160 to fill the connecting hole 160 during the process of printing and forming the covering portion 141, and the above-mentioned conductive pillar 170 will be formed after curing, serving as a physical conductive channel. The surface of the conductive pillar 170 is in full contact with the inner wall of the corresponding connecting hole 160. In this way, the nano metal wires in the metal wire layer 120 form sufficient contact with the conductive ink in the conductive pillar 170 at the inner wall of the connecting hole 160, thereby establishing a good electrical connection between the metal wire layer 120 and the lead structure 140, so that the electrical signal generated by the metal wire layer 120 can be transmitted to other electronic devices through the lead structure 140. In a further preferred embodiment, the connecting hole 160 completely penetrates the metal wire layer 120, that is, the bottom of the connecting hole 160 reaches the surface of the substrate layer 110; in this way, when the lead structure 140 is formed, the end of the conductive pillar 170 can be directly bonded to the substrate layer 110, which is beneficial to enhance the firmness of the lead structure 140, and the cooperation of the lead structure 140 and the substrate layer 110 can also be used to make the bonding of the metal wire layer 120 and the protective layer 150 more stable, so as to improve the overall structural strength.

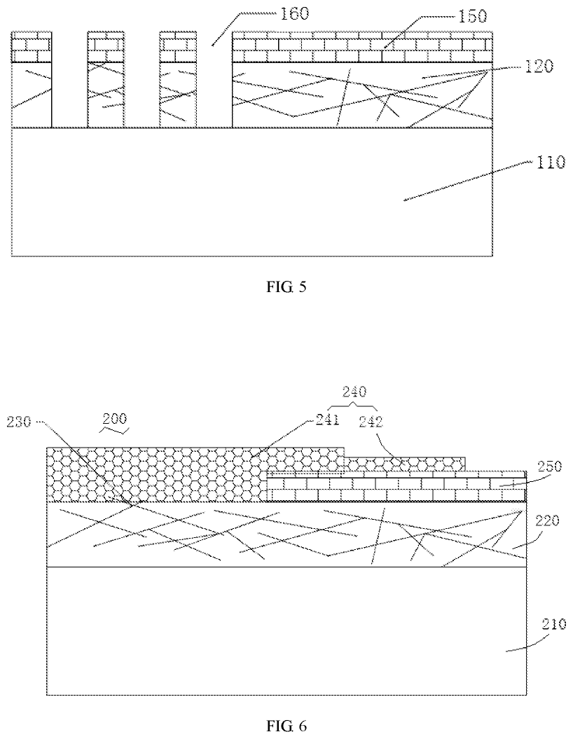

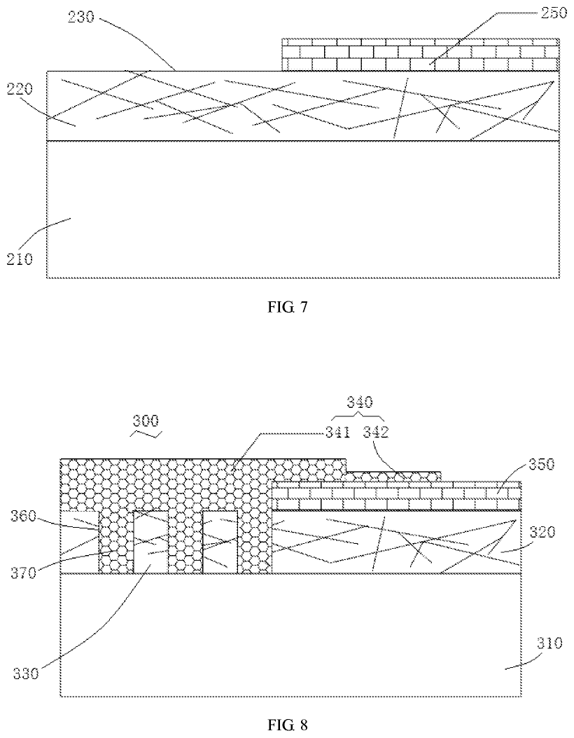

Please refer to FIG. 6, another preferred embodiment of the present disclosure provides a flexible touch sensor electrode 200. Most of the structures of the flexible touch sensor electrode 200 are similar to the above-mentioned flexible touch sensor electrode 100, and the main difference between the flexible touch sensor electrode 200 and the above-mentioned flexible touch sensor electrode 100 is that in the flexible touch sensor electrode 200, the protective layer 250 on the contact area 230 of the metal wire layer 220 is completely or partially removed, but the contact area 230 is not provided with a connecting hole; the covering portion 241 of the lead structure 240 covers a certain area of the surface of the transparent conductive film, preferably on the entire surface of the contact area 230; and the part of the contact area 230 that is not covered by the protective layer 250 is directly covered and contacted by the covering portion 241 of the lead structure 240 completely.

In the above-mentioned flexible touch sensor electrode 200, both sides of the metal wire layer 220 are respectively protected by the substrate layer 210 and the protective layer 250, which can effectively prevent the metal wire layer 220 from being damaged by external contaminants. In the contact area 230, the protective layer 250 is completely or partially removed, and the top portion of the metal wire layer 220 (that is, the surface of the contact area 230 facing away from the substrate layer 210) can directly contact the covering portion 141 of the lead structure 140. Therefore, it is ensured that a good electrical connection is established between the metal wire layer 220 and the lead structure 240 without being hindered by the protective layer 250. Since the protective layer 250 does not hinder the electrical connection between the metal wire layer 220 and the lead structure 240, the protective layer 250 can be manufactured to have a sufficient thickness, to provide sufficient protection for the metal wire layer 220, so as to effectively improve the reliability of the flexible touch sensor electrode 200 and prolong the service life.

Another embodiment of the present disclosure also provides a method for manufacturing a flexible touch sensor electrode, and the method can be used to manufacture the flexible touch sensor electrode 200 as described above. Please refer to FIG. 7 together, the method may include the following steps:

S21, forming the substrate layer 210 of the transparent conductive film. For this step, reference may be made to the above-mentioned step S11, which does not need to be repeated here.

S22, forming the metal wire layer 220 on the substrate layer 210. For this step, reference may be made to the above-mentioned step S12, which does not need to be repeated here.

S23, forming the protective layer 250 on the metal wire layer 220. For this step, reference may be made to the above-mentioned step S13, which does not need to be repeated here.

S24, determining a contact area 230 on the metal wire layer 220, and removing all or part of the protective layer 250 on the contact area 230, as shown in the FIG. 7. The specific operation means of removing the protective layer 250 on the contact area 230 can be selected such as laser etching, chemical wet etching, and physical cutting die imprinting.

S25, forming the above-mentioned lead structure 240 including a covering portion 241 and a leading-out portion 242, as shown in FIG. 6, so that the covering portion 241 covers the contact area 230 and directly contacts the contact area 230 to establish an electrical connection, wherein the leading-out portion 242 extends from the covering portion 241 to electrically connect the metal wire layer 220 with the outside. In this step S25, the conductive ink may be printed on the transparent conductive film, for example, the conductive ink may be printed on the surface of the contact area 230 to form the covering portion 241 of the lead structure 240, and further a leading-out portion 242 extending from the covering portion 241 is printed on the protective layer 250 outside the contact area 230, for electrical connection with other electronic devices. Meanwhile, since the protective layer 250 on the surface of the contact area 230 has been completely or partially removed, the conductive ink will directly cover and fully contact the area on the surface of the contact area 230 that is not covered by the protective layer 250 during the process of forming the covering portion 241 by printing, thereby forming a good electrical connection between the lead structure 240 and the metal wire layer 220, so that the electrical signal generated by the metal wire layer 220 can be transmitted to other electronic devices through the lead structure 240.

Please refer to FIG. 8, yet another preferred embodiment of the present disclosure provides a flexible touch sensor electrode 300. Most of the structures of the flexible touch sensor electrode 300 are similar to the above-mentioned flexible touch sensor electrodes 100 and 200, and the main difference between the flexible touch sensor electrode 300 and the above-mentioned flexible touch sensor electrodes 100 and 200 is that in the flexible touch sensor electrode 300, the protective layer 350 on the contact area 330 of the metal wire layer 320 is completely or partially removed, meanwhile, the contact area 330 is also provided with a plurality of connecting holes 360 extending to the inside of the metal wire layer 320, and the connecting holes 360 preferably completely penetrate the metal wire layer 320, that is, extend to the surface of the substrate layer 310; the covering portion 341 of the lead structure 340 covers a certain area of the surface of the transparent conductive film, preferably on the entire surface of the contact area 330; and the part of the contact area 330 that is not covered by the protective layer 350 is directly covered and contacted by the covering portion 341 of the lead structure 340, and meanwhile, the lead structure 340 is also provided with conductive pillars 370 corresponding to the connecting holes 360 in number, shape and size, wherein the conductive pillar 370 is a columnar portion extending from the bottom of the covering portion 341 of the lead structure 340, and is inserted into the connecting hole 360 to serve as a physical conductive channel.

In the above-mentioned flexible touch sensor electrode 300, both sides of the metal wire layer 320 are respectively protected by the substrate layer 310 and the protective layer 350, which can effectively prevent the metal wire layer 320 from being damaged by external contaminants. In the contact area 330, the protective layer 350 is completely or partially removed, and the top portion of the metal wire layer 220 (that is, the surface of the contact area 330 facing away from the substrate layer 310) can directly contact the covering portion 341 of the lead structure 340; meanwhile, the surface of the conductive pillar 370 can also fully contact the inner wall of the corresponding connecting hole 360, that is, the nano metal wire in the metal wire layer 320 is in sufficient contact with the conductive ink in the conductive pillar 370 at the inner wall of the connecting hole 360; and both of the above two contact methods can ensure that a good electrical connection is established between the metal wire layer 320 and the lead structure 340 without being hindered by the protective layer 350. Since the protective layer 350 does not hinder the electrical connection between the metal wire layer 320 and the lead structure 340, the protective layer 350 can be manufactured to have a sufficient thickness, to provide sufficient protection for the metal wire layer 320, so as to effectively improve the reliability of the flexible touch sensor electrode 300 and prolong the service life.

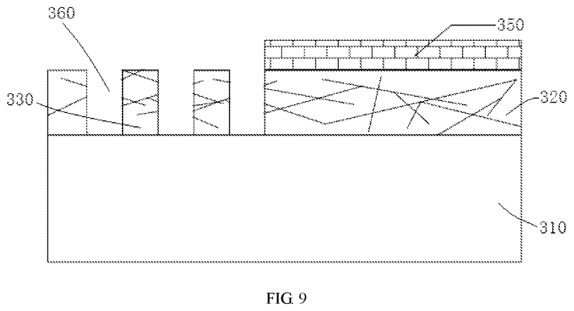

Another embodiment of the present disclosure also provides a method for manufacturing a flexible touch sensor electrode, and the method can be used to manufacture the flexible touch sensor electrode 200 as described above. Please refer to FIG. 9 together, the method may include the following steps:

S31, forming the substrate layer 310 of the transparent conductive film. For this step, reference may be made to the above-mentioned step S11, which does not need to be repeated here.

S32, forming the metal wire layer 320 on the substrate layer 310. For this step, reference may be made to the above-mentioned step S32, which does not need to be repeated here.

S33, forming a protective layer 350 on the metal wire layer 320. For this step, reference may be made to the above-mentioned step S33, which does not need to be repeated here.

S34, determining a contact area 330 on the metal wire layer 320, and removing all or part of the protective layer 350 on the contact area 330, as shown in FIG. 9. The specific operation means of removing the protective layer 350 on the contact area 330 can be selected such as laser etching, chemical wet etching, and physical cutting die imprinting.

S35, performing a perforation treatment in the area of the contact area 330 where the protective layer 350 is removed, and forming the above-mentioned connecting hole 360 extending into (preferably passing through) the metal wire layer 320 in this area, as shown in FIG. 9. The specific operation means of the perforation treatment can be selected such as laser etching, chemical wet etching, and physical cutting die imprinting.

S36, forming the above-mentioned lead structure 340 including a covering portion 341 and a leading-out portion 342, as shown in FIG. 8, so that the covering portion 341 covers the contact area 330 and directly contacts the contact area 330 to establish an electrical connection, wherein the leading-out portion 342 extends from the covering portion 341 to electrically connect the metal wire layer 320 with the outside. In this step S36, the conductive ink may be printed on the transparent conductive film, for example, the conductive ink may be printed on the surface of the contact area 330 to form the covering portion 341 of the lead structure 340, and further a leading-out portion 342 extending from the covering portion 341 is printed on the protective layer 350 outside the contact area 330, for electrical connection with other electronic devices. In the process of printing and forming the covering portion 341, since the protective layer 350 on the surface of the contact area 330 has been completely or partially removed, the conductive ink will directly cover and fully contact the area on the surface of the contact area 330 that is not covered by the protective layer 350. At the same time, since the above-mentioned connecting hole 360 is also formed in the contact area 330, the conductive ink will also enter the connecting hole 360 to fill the connecting hole 360. After curing, the above-mentioned conductive pillar 370 is formed, which serves as a physical conductive channel. The surface of the conductive pillar 370 is in full contact with the inner wall of the corresponding connecting hole 360. In this way, the nano metal wires in the metal wire layer 320 form sufficient contact with the conductive ink in the conductive pillar 370 at the inner wall of the connecting hole 360. Both of the above two contact methods can establish a good electrical connection between the metal wire layer 320 and the lead structure 340, so that the electrical signal generated by the metal wire layer 320 can be transmitted to other electronic devices through the lead structure 340.

In the flexible touch sensor electrodes 100, 200, 300 provided in the above embodiments and their various equivalent alternatives, the surfaces of both sides of the metal wire layer are respectively protected by the substrate layer and the protective layer, which can effectively prevent the metal wire layer from being damaged by external contaminants; within the range of the contact area, the protective layer is completely or partly removed to expose the metal wire layer, and further connecting holes for allowing the lead structure to extend to the inside of the metal wire layer can be provided to ensure that the contact between the metal wire layer and the lead structure is not hindered by the protective layer, so as to establish a good electrical connection between the metal wire layer and the lead structure, and thus improve the electrical performance of the flexible touch sensor electrode; and since the protective layer does not hinder the electrical connection between the metal wire layer and the lead structure in the contact area, the protective layer can be manufactured to have a sufficient thickness to provide sufficient protection for the metal wire layer, so as to significantly improve the reliability of the flexible touch sensor electrode and prolong the service life, thereby effectively solving the problem in the prior art that the protective layer of the flexible touch sensor electrode has poor protection effect and may also affect the electrical performance.

The above-mentioned are only the preferred embodiments of the present disclosure and are not intended to limit the present disclosure. Any modification, equivalent replacement, improvement, etc. made within the spirit and principle of the present disclosure shall be included within the scope of protection of the present disclosure.

1. A flexible touch sensor electrode, comprising a substrate layer, a metal wire layer, a protective layer and a lead structure, wherein the substrate layer is made of a flexible insulating material; the metal wire layer is a flexible film layer comprising nano metal wires, the metal wire layer covers at least part of a surface of the substrate layer and is configured to sense an external touch operation and generate a corresponding electrical signal according to the touch operation; the protective layer is made of a flexible insulating material and covers at least part of a surface of the metal wire layer facing away from the substrate layer; and the metal wire layer is provided with a contact area configured to establish an electrical connection to an outside, and within a range of the contact area, the protective layer is at least partially removed; and the lead structure comprises a covering portion and a leading-out portion, wherein the covering portion covers the contact area and directly contacts the contact area so as to establish an electrical connection, and wherein the leading-out portion extends from the covering portion and is configured to electrically connect the metal wire layer and the outside.

2. The flexible touch sensor electrode according to claim 1, wherein a connecting hole extending to an inside of the metal wire layer is provided in the range of the contact area, a conductive pillar corresponding to the connecting hole is formed at a bottom of the covering portion, and the conductive pillar extends into the connecting hole and contacts the metal wire layer at an inner wall of the connecting hole, thereby establishing an electrical connection between the metal wire layer and the lead structure.

3. The flexible touch sensor electrode according to claim 2, wherein the connecting hole completely penetrates the metal wire layer and extends to the surface of the substrate layer, and an end of the conductive pillar is directly connected to the substrate layer.

4. The flexible touch sensor electrode according to claim 2, wherein within the range of the contact area, a portion of the protective layer corresponding to the connecting hole is removed.

5. The flexible touch sensor electrode according to claim 1, wherein all parts of the contact area that are not covered by the protective layer are directly covered and contacted by the covering portion.

6. The flexible touch sensor electrode according to claim 1, wherein the covering portion further covers a part of the protective layer outside the range of the contact area.

7. The flexible touch sensor electrode according to claim 1, wherein the substrate layer, the metal wire layer and the protective layer are all transparent flexible films.

8. The flexible touch sensor electrode according to claim 7, wherein the substrate layer is made of an amorphous polymer material.

9. The flexible touch sensor electrode according to claim 7, wherein the protective layer is made of an etchable polymer resin material or an inorganic oxide material.

10. The flexible touch sensor electrode according to claim 7, wherein the lead structure is made of conductive ink by printing.

11. A method for manufacturing a flexible touch sensor electrode, comprising:
forming a substrate layer;
forming a metal wire layer on the substrate layer;
forming a protective layer on the metal wire layer;
determining a contact area on the metal wire layer, and removing at least a part of the protective layer on the contact area; and
forming a lead structure comprising a covering portion and a leading-out portion, so that the covering portion covers the contact area and directly contacts the contact area to establish an electrical connection, and the leading-out portion extends from the covering portion, so as to electrically connect the metal wire layer and an outside.

12. The method according to claim 11, wherein the forming a metal wire layer on the substrate layer comprises:
mixing nano metal wires in a solvent to form a nano metal wire dispersion;
coating the nano metal wire dispersion on the substrate layer;
volatilizing the solvent in the nano metal wire dispersion through drying treatment; and
fixing the nano metal wires on the substrate layer by fixing treatment.

13. The method according to claim 11, wherein the forming a protective layer on the metal wire layer comprises:
selecting an etchable polymer resin material or an inorganic oxide material as a material of the protective layer; and
coating the material of the protective layer on the metal wire layer by at least one of printing, spraying, physical deposition, chemical deposition and electroplating.

14. The method according to claim 11, wherein the removing at least a part of the protective layer on the contact area comprises:
performing a perforation treatment in a range of the contact area by at least one of laser etching, chemical wet etching and physical cutting die imprinting, so as to form a connecting hole that completely penetrates the protective layer and extends into the metal wire layer, so that a part of the protective layer corresponding to the connecting hole is removed.

15. The method according to claim 11, wherein the removing at least a part of the protective layer on the contact area comprises:
removing at least a part of the protective layer on the contact area by at least one of laser etching, chemical wet etching and physical cutting die imprinting.

16. The method according to claim 15, wherein the forming a lead structure comprising a covering portion and a leading-out portion comprises:
printing conductive ink on a surface of the contact area to form the covering portion; and
printing the leading-out portion extending from the covering portion with the conductive ink on the protective layer outside the contact area.

17. The method according to claim 15, further comprising:
performing a perforation treatment in an area of the contact area where the protective layer is removed by at least one of laser etching, chemical wet etching and physical cutting die imprinting, so as to form a connecting hole extending into the metal wire layer in the area.

18. The method according to claim 14, wherein the forming a lead structure comprising a covering portion and a leading-out portion comprises:
printing conductive ink on a surface of the contact area to form the covering portion; at the same time, enabling the conductive ink to enter the connecting hole to fill the connecting hole, so as to form, after curing, a conductive pillar configured to establish electrical connection with the metal wire layer through contact; and
printing the leading-out portion extending from the covering portion with the conductive ink on the protective layer outside the contact area.

19. The flexible touch sensor electrode according to claim 3, wherein within the range of the contact area, a portion of the protective layer corresponding to the connecting hole is removed.

20. The method according to claim 17, wherein the forming a lead structure comprising a covering portion and a leading-out portion comprises:
printing conductive ink on a surface of the contact area to form the covering portion; at the same time, enabling the conductive ink to enter the connecting hole to fill the connecting hole, so as to form, after curing, a conductive pillar configured to establish electrical connection with the metal wire layer through contact; and
printing the leading-out portion extending from the covering portion with the conductive ink on the protective layer outside the contact area.
